(19) United States
(12) Patent Application Publication
(10) Pub. No.: US 2013/0037110 A1
(43) Pub. Date: Feb. 14, 2013

(54) Particle-Based Precursor Formation Method and Photovoltaic Device Thereof

(71) Applicants: David Brian Mitzi, Mahopac, NY (US); Teodor Krassimirov Todorov, Yorktown Heights, NY (US)

(72) Inventors: David Brian Mitzi, Mahopac, NY (US); Teodor Krassimirov Todorov, Yorktown Heights, NY (US)

(73) Assignee: International Business Machines Corporation, Armonk, NY (US)

(21) Appl. No.: 13/207,187

(22) Filed: Aug. 10, 2011

(51) Int. Cl. H01L 31/0272; B05D 7/24; B05D 3/02; H01L 21/20; C09D 11/00

(52) U.S. Cl. 136/264; 438/478; 106/31.13; 427/372.2; 257/E21.09

(57) ABSTRACT

Techniques for fabrication of kesterite Cu—Zn—Sn—(Se,S) films and improved photovoltaic devices based on these films are provided. In one aspect, a method of forming metal chalcogenide nanoparticles is provided. The method includes the following steps. Water, a source of Zn, a source of Cu, optionally a source of Sn and at least one of a source of S and a source of Se are contacted under conditions sufficient to produce a dispersion of the metal chalcogenide nanoparticles having a Zn chalcogenide distributed within a surface layer thereof. The metal chalcogenide nanoparticles are separated from the dispersion and can subsequently be used to form an ink for deposition of kesterite films.

### FIELD OF THE INVENTION

The present invention relates to a liquid-based method for deposition of inorganic films having copper (Cu), zinc (Zn), tin (Sn), and at least one of sulfur (S) and selenium (Se) and more particularly, to techniques for fabrication of kesterite Cu—Zn—Sn—(Se,S) films and improved photovoltaic devices based on these films.

### BACKGROUND OF THE INVENTION

The widespread implementation of next generation ultra-large scale photovoltaic technologies (beyond 100 gigawatt peak (GWp)) will require drastically reducing production costs and achieving high efficiency devices using abundant, environmentally friendly materials. Thin-film chalcogenide-based solar cells provide a promising pathway to cost parity between photovoltaic and conventional energy sources. Currently, only Cu(In,Ga)(S,Se)₂ and CdTe technologies have reached commercial production and offer over 10 percent power conversion efficiency. These technologies generally employ (i) indium (In) and tellurium (Te), which are relatively rare elements in the earth's crust, or (ii) cadmium (Cd), which is a highly toxic heavy metal.

Copper-zinc-tin-chalcogenide compounds with kesterite crystalline structure and the ideal formula Cu₂ZnSn(S,Se)₄, have been investigated as potential alternatives because they are based on readily available and lower cost elements. However, photovoltaic cells with said kesterites, even when produced using high cost vacuum-based methods, had until recently achieved only about 6.7 percent efficient devices, see H. Katagiri et al., “Development of CZTS-based thin film solar cells,” Thin Solid Films 517, 2455-2460 (2009).

U.S. Patent Application Publication Number 2011/0094557 A1, filed by Mitzi et al., entitled “Method of Forming Semiconductor Film and Photovoltaic Device Including the Film,” and T. Todorov et al., “High-Efficiency Solar Cell with Earth-Abundant Liquid-Processed Absorber,” Adv. Mater. 22, E156-E159 (2010), describe a hydrazine-based approach for depositing homogeneous chalcogenide layers from mixed slurries containing both dissolved and solid metal chalcogenide species dispersed in systems that do not require organic binders. Upon anneal, the particle-based precursors readily react with the solution component and form large-grained films with good electrical characteristics and device power conversion efficiencies of as high as 10%.

Improper handling of pure hydrazine, however, can lead to a risk of ignition. Therefore, the use and transportation of pure hydrazine is regulated by the federal government (e.g., see Eckart W. Schmidt, “Hydrazine and its Derivatives: Preparation, Properties, Applications,” Wiley-Interscience, pgs. 778-783 (2001)). Pure hydrazine vapors are particularly dangerous. In the absence of a diluent gas (such as ammonia, water vapor or nitrogen), pure hydrazine vapors may explode if ignited. By contrast, other inflammable solvents require oxygen to form explosive mixtures. Transportation and use of pure hydrazine in manufacturing therefore requires rigorous and expensive handling protocols in order to assure safe large-scale photovoltaic manufacturing based on conventional methods.

A first step towards reducing hydrazine content was taken in U.S. Patent Application Publication Number 2011/0097496 A1, filed by Mitzi et al., entitled “Aqueous-Based Method of Forming Semiconductor Film and Photovoltaic Device Including the Film,” and T. Todorov et al., “Progress towards marketable earth-abundant chalcogenide solar cells,” Thin Solid Films (2011) in press (available on-line, doi:10.1016/j.tsf.2010.12.225). Pure hydrazine solutions were diluted up to 50% with water or ammonium hydroxide. However, in solutions with a high sulfur or selenium content these dilutions may still be insufficient to prevent hazardous thermal decomposition. Tests have determined that 40% hydrazine is a safety threshold for hydrazine-sulfur solutions with respect to ignition. Attempts to further dilute the previously employed solutions have led to large crystallites and inks of poor quality. Furthermore, even if successful, this process of using diluted hydrazine would still require using highly-concentrated hydrazine in the preparation step.

Alternative, hydrazine-free hot-injection particle-based approaches have also been reported that employ particles of a pre-determined size. T. Todorov, et al., “Cu₂ZnSnS₄ films deposited by a soft-chemistry method,” Thin Solid Films, 517, 2541-2544 (2009) describes a deposition approach based on quaternary Cu—Zn—Sn—S precursors formed by reacting metal acetates and chlorides with elemental sulfur in ethylene glycol at 170° C. Films deposited by a similar approach, employing oleylammine solvent at 225° C. have also been reported. See, for example, PCT Application Publication Number WO2010/138636 A2, entitled “Synthesis of Multinary Chalcogenide Nanoparticles Comprising Cu, Zn, Sn, S and Se”; Guo et al., “Synthesis of Cu₂ZnSnS₄ nanocrystal ink and its use for solar cells,” J. Amer. Chem. Soc., 131, 11672-11673 (2009) and Guo et al., “Fabrication of 7.2% Efficient CZTSSe Solar Cells Using CZTS Nanocrystals,” J. Am. Chem. Soc., 132, 17384-17386 (2010). Films were subjected to selenization treatment leading to a reported power conversion efficiency of 7.2%. Other hot injection methods, including those in ionic liquids have also been reported. See, for example, PCT Application Publication Number WO2011/065994 A2, entitled “CZTS/Se Precursor Inks and Methods for Preparing CZTS/Se Thin Films and CZTS/Se-Base Photovoltaic Cells,” PCT Application Publication Number WO/2011066273 A1, entitled “Preparation of CZTS and its Analogs in Ionic Liquids” and PCT Application Publication Number WO2011/066256 A1, entitled “Screen-Printable Quaternary Chalcogenide Compositions.” However, hot injection approaches may not be preferred for industrial production because they require the use of large volumes of expensive organic solvents, employ hazardous temperatures above the flash points of these solvents and generate large volumes of malodorous organic residues.

Aqueous-based routes are preferable for large-scale industrial manufacturing due to superior safety characteristics as well as lower costs both for raw materials and residue management. Aqueous synthesis routes to crystalline chalcogenide particles including CZTS have been reported and used for film formation. See, for example, PCT Application Publication Number WO2011/066205 A1, entitled “Aqueous Process for Producing Crystalline Copper Chalcogenide Nanoparticles, the Nanoparticles So-Produced, and Inks and Coated Substrates Incorporating the Nanoparticles” (hereinafter “PCT Application Publication Number WO2011/066205 A1”). Despite the attempt to claim a broad range of classic chalcogenide formation routes in water, PCT Application Publication Number WO2011/066205 A1 does not teach a specific aqueous route to a high-quality film and a device thereof with reasonable efficiency. In addition, the examples given employ organic compounds, reactions at elevated temperatures and require the use of ligands and dispersing additives.

Therefore, improved aqueous, particle-based thin-film chalcogenide solar cell fabrication techniques would be desirable.

### SUMMARY OF THE INVENTION

The present invention provides techniques for fabrication of kesterite Cu—Zn—Sn—(Se,S) films and improved photovoltaic devices based on these films. In one aspect of the invention, a method of forming metal chalcogenide nanoparticles is provided. The method includes the following steps. Water, a source of Zn, a source of Cu, optionally a source of Sn and at least one of a source of S and a source of Se are contacted under conditions sufficient to produce a dispersion of the metal chalcogenide nanoparticles having a Zn chalcogenide distributed within a surface layer thereof. The metal chalcogenide nanoparticles are separated from the dispersion.

In another aspect of the invention, a method for forming an ink for fabricating a kesterite film having a formula Cu₂₋ₓZn_{1+y}Sn(S_{1-z}Se_{z})_{4+q}, wherein 0≦x≦1; 0≦y≦1; 0≦z≦1; −1≦q≦1, is provided. The method includes the following steps. Metal chalcogenide nanoparticles are formed according to the above method. The metal chalcogenide nanoparticles are dispersed in a solvent to form the ink, wherein the ink has a pH of from about 7 to about 14.

In yet another aspect of the invention, a method of forming a kesterite film having a formula Cu₂₋ₓZn_{1+y}Sn(S_{1-z}Se_{z})_{4+q}, wherein 0≦x≦1; 0≦y≦1; 0≦z≦1; and −1≦q≦1 is provided. The method includes the following steps. An ink is formed according to the above method. The ink is deposited onto a substrate to form a layer on the substrate. The layer is heated at a temperature and for a duration sufficient to form the kesterite film.

In still yet another aspect of the invention, a photovoltaic device with power conversion efficiency greater than 6% is provided. The photovoltaic device includes a substrate; a kesterite film absorber layer having a formula Cu₂₋ₓZn_{1+y}Sn(S_{1-z}Se_{z})_{4+q}, wherein 0≦x≦1; 0≦y≦1; 0≦z≦1; and −1≦q≦1 formed on the substrate by the above method; an n-type semiconducting layer on the kesterite film; and a top electrode on the n-type semiconducting layer.

A more complete understanding of the present invention, as well as further features and advantages of the present invention, will be obtained by reference to the following detailed description and drawings.

### BRIEF DESCRIPTION OF THE DRAWINGS

FIG. 1 is a diagram illustrating an exemplary methodology for forming a kesterite film according to an embodiment of the present invention;

FIG. 2 is a cross-sectional diagram illustrating a starting structure for fabricating a photovoltaic device, e.g., a substrate formed from a conductive material or a substrate coated with a layer of conductive material according to an embodiment of the present invention;

FIG. 3 is a cross-sectional diagram illustrating a kesterite film absorber layer having been formed on the substrate according to an embodiment of the present invention;

FIG. 4 is a cross-sectional diagram illustrating an n-type semiconducting layer having been formed on the kesterite film and a top electrode having been formed on the n-type semiconducting layer according to an embodiment of the present invention;

FIG. 5 is an image of a kesterite film prepared using the present techniques according to an embodiment of the present invention;

FIG. 6 is a graph illustrating current density-voltage characteristics of an exemplary solar cell device fabricated using the present techniques according to an embodiment of the present invention;

FIG. 7 is an image of a kesterite film prepared using the present techniques including a treatment with tin sulfide (SnS) and sulfur (S) vapor according to an embodiment of the present invention;

FIG. 8 is an image of a kesterite film prepared using the present techniques including a treatment with SnS and selenium (Se) vapor according to an embodiment of the present invention; and

FIG. 9 is a table illustrating current-voltage characteristics of another exemplary solar cell device fabricated using the present techniques according to an embodiment of the present invention.

### DETAILED DESCRIPTION OF PREFERRED EMBODIMENTS

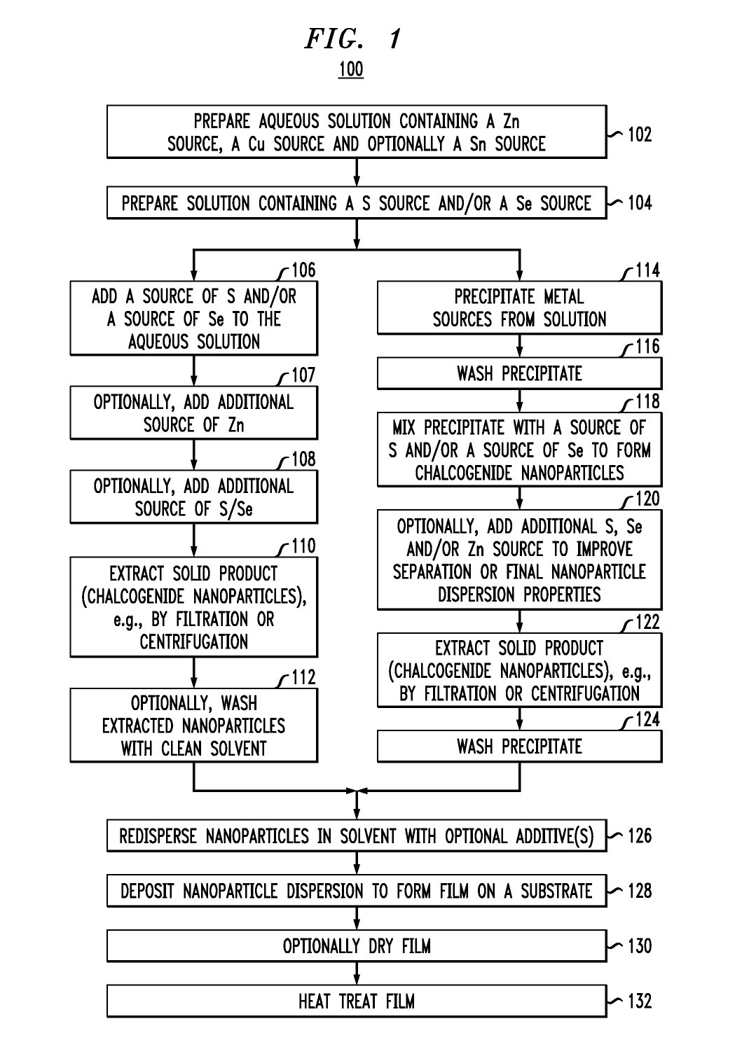

FIG. 1 is a diagram illustrating an exemplary methodology 100 for forming a kesterite Cu—Zn—Sn—(Se,S) film. Said kesterite films employ common, readily available elements, such as copper (Cu), zinc (Zn), tin (Sn), sulfur (S) and selenium (Se). For a general discussion on kesterite and use of kesterite in solar cells, see for example, Schorr, “The crystal structure of kesterite type compounds: A neutron and x-ray diffraction study,” Solar Energy Materials and Solar Cells, vol. 95, 1482-1488 (2011), the entire contents of which is incorporated by reference herein. In the following description, when components are defined as containing elements, it is to be understood that these elements can be present in either isolated or in compound form, e.g., a Zn-containing component may contain Zn, zinc sulfide (ZnS), zinc selenide (ZnSe), zinc oxide (ZnO), zinc hydroxide (Zn(OH)₂) or any other known Zn compound. Likewise, the term “solution” is used in a broader sense and may comprise a pure solution or a dispersion.

The present techniques provide zinc-stabilized dispersible compositions that do not require incorporation of organic compounds, heat treatment during the synthesis reactions or a heat treatment for the particles to produce a chalcogenide ink. The method for producing the inks and light absorbing semiconductor film thereof are suitable for ultrahigh throughput production at minimized cost. The dispersible compositions can be obtained by any standard water-based synthesis route known to the skilled in the art as long as conditions delivering an amount of Zn species within the surface layer of the particles are provided.

Not being limited to the following theory, the principle of the present techniques could be related to a phenomenon viewed as problematic for the separation of mineral dispersions. It was observed that even strongly hydrophobic materials, such as copper sulfides have relatively low flotation rate constants in the presence of Zn (T. H. Muster et. al., “Rheological Investigations of Sulphide Mineral Slurries,” Minerals Engineering, Vol. 8, No. 12, pp. 1541-1555 (1995), the entire contents of which are incorporated by reference herein). Prestidge et al., “Copper (II) activation and cyanide deactivation of zinc sulphide under mildly alkaline conditions,” Applied Surface Science 108, pp. 333-344 (1997) (hereinafter “Prestidge”), the entire contents of which are incorporated by reference herein, describe thermodynamically unstable surface phases under alkaline conditions (pH=9) where copper-zinc exchange occurs:

(ZnS)ₙ.Cu(OH)₂←→Znₙ₋ₓCuₓSₙ₋ₓZn(OH)₂.

Prestidge describes that, even when starting with ZnS particles and copper solutions, after aging with pH 9 conditions for one week the majority of the copper diffuses into the particles and the surfaces have elevated content of Zn, S and O. Since Zn-based chalcogenides are observed to disperse better than copper-based materials, the migration of the Zn to the surface layer of the particles is expected to enable more stable dispersions (i.e., not prone to separation). By analogy, in the current situation of the nanoparticles based on Cu, Zn, Sn, S and Se, the combination of Zn(S,Se) precipitation and basic conditions is expected to improve dispersion properties without resorting to organic stabilizing or dispersing agents.

To begin the present process, metal chalcogenide nanoparticles are produced. Specifically, in step 102, a first solution, i.e., an aqueous metal source solution and/or dispersion, is prepared containing a source of Zn, a source of Cu and optionally a source of Sn (i.e., Sn may optionally be introduced later in the process as a vapor). According to an exemplary embodiment, the metal source solution is prepared by dissolving a Zn-source compound, a Cu-source and optionally a Sn-source compound in water as the solvent. Suitable Zn, Cu and Sn-source compounds include, but are not limited to, elemental Zn, zinc oxide, zinc hydroxide, zinc bromide, zinc fluoride, zinc iodide, zinc chloride, zinc sulphate, zinc nitrate, elemental Cu, copper oxide, copper hydroxide, copper bromide, copper fluoride, copper iodide, copper chloride, copper sulphate, copper nitrate, elemental Sn, tin oxide, tin hydroxide, tin bromide, tin fluoride, tin iodide, tin chloride, tin sulphate and tin nitrate. Metal sources are not limited to the above examples and are not limited to crystalline compounds detectable by x-ray diffraction techniques, but may include any amorphous and/or mixed compounds of the above, such as but not limited to zinc oxy-sulphides. Namely, amorphous compounds may feature enhanced reactivity and the ability to disperse in water media without the need of organic additives. When added to water, these sources may only partially dissolve, which is suitable for the present techniques. Optionally, full dissolution can be achieved by adjusting the pH of the solution through the addition of an acid(s), such as but not limited to hydrochloric acid (HCl) in concentrations of from about 0.01 molar (M) to about 10 M in the final solution or, alternatively addition of a complex forming agent such as but not limited to ammonia or ammonium hydroxide in any concentration above 0.01 M.

According to an exemplary embodiment, the total concentration of metals including Zn, Cu and Sn in the source solution is from about 0.01 M to about 5 M, e.g., from about 0.05 M to about 1 M, and a ratio between the metals ideally corresponds to the targeted ratio in the final product, for example, Cu/Zn/Sn=1.6/1.22/1. In the cases where some of the metals are found to redissolve during processing, as may be the case with Sn and the other metals during washing step (see below), either the starting concentration can be adjusted to compensate for this, or an adjustment amount of Sn (or alternatively Zn and/or Cu) source can be added to the final ink before film deposition (see below).

In step 104, a second solution, i.e., chalcogen source solution containing a source of S and/or a source of Se, is prepared. According to an exemplary embodiment, this S and/or Se source solution is formed by dissolving a S and/or Se source compound in a suitable solvent. According to an exemplary embodiment, the S source compound is ammonium sulfide, alkali metal sulfide or hydrogen sulfide, the Se source compound is ammonium selenide, alkali metal selenide or hydrogen selenide and the solvent is water.

Preferably, the total molar concentration of the chalcogen sources is greater than or equal to the total molar concentration of the metal sources. Although the formation of nanoparticles with kesterite structure in the ink preparation steps is acceptable, the exemplary embodiment does not target the formation of kesterite phase before film deposition. In specific cases the presence of binary and/or amorphous phases in the inks may enhance the ability to grow large kesterite grains during the high-temperature crystallization step in contrast to pre-crystallized kesterite nanoparticles featuring reduced reactivity and greater number of nucleation centers.

The chalcogenide nanoparticle formation process then involves contacting the metal sources with the chalcogen source(s) and extracting a solid product from the solution. As indicted in FIG. 1, these steps can be performed in a number of different ways. For example, in step 106, the chalcogen source solution is mixed with the aqueous metal source solution (the combined solutions referred to hereinafter as a reactant solution). Of course, whether Cu, Sn or both Cu and Sn are present in the aqueous metal source solution and whether S, Se or both S and Se are present in the chalcogen source solution depends on the desired composition or compositional profile of the nanoparticles and keserite film formed therefrom. Adding an equimolar amount of chalcogen source to the metal source may be sufficient to facilitate the formation of the targeted product. However, depending on the reaction conditions and pH, affecting the surface equilibria described by Prestidge (see above), adding an excess source of chalcogen, from about 0.05 times to about 5 times the molar amount of the metal source, may be beneficial for the fabrication process, enabling easier separation and higher purity of the product, particularly with respect to oxide contamination.

In a preferred embodiment, mixing the chalcogen source solution with the aqueous metal source solution effects the formation of metal chalcogenide nanoparticles that are capable of forming dispersions suitable for ink-based film deposition without the need for organic nanoparticle capping agents and without the need for elevated temperatures during particle formation. Namely, according to an exemplary embodiment, the temperature of the reaction to form the nanoparticles is maintained at or near room temperature during the nanoparticle fabrication step. By way of example only, a temperature of from about 0 degrees Celsius (° C.) to about 100° C., e.g., from about 20° C. to about 50° C., is employed.

As highlighted above, in accordance with the present teachings it is desirable to provide zinc-stabilized dispersible compositions with a predominate amount of the Zn chalcogenide in the particles being present within the surface layers of the particles. Enough Zn chalcogenide should be distributed within the surface layers of the nanoparticles so as to inhibit chalcogenide nanoparticle agglomeration in water at a pH of from about 7 to about 14 advantageously without the use of organic additives or ligands.

As described above, this Zn chalcogenide-rich surface layer can be accomplished by taking advantage of thermodynamically unstable surface phases which, under alkaline conditions, cause copper-zinc exchange to occur. A Zn-chalcogenide rich surface layer on the nanoparticles may also be accomplished by adding (additional) Zn source compound to the reactant solution which serves to enhance precipitate quality by capping the nanoparticles with Zn compounds. Thus, according to an exemplary embodiment, a Zn content within the surface layers of the nanoparticles is greater than a Zn content in the bulk volume of the nanoparticles. The distribution of Zn within the surface layer can be homogeneous or graded (layered), as long as the average Zn concentration in this surface layer exceeds that of the Zn concentration of the bulk volume of the nanoparticles. The “surface layer of the nanoparticles” is the interface layer between the particle and the solution and may comprise a layer from an atomic or molecular thickness to a layer of about 0.25 times the diameter of the particle and may comprise either zinc chalcogenide compounds or mixed Cu(Sn)—Zn chalcogenides or oxychalcogenides with a content of zinc greater than the average zinc concentration. Depending on the specific morphology, this concentration difference can be measured by XPS and ICP or TEM EDX scanning of individual particles. Forming a Zn-rich cap on the nanoparticles can be accomplished, for example, by contacting the nanoparticles with a solution containing Zn²⁺ ions (hereinafter “a Zn solution”). Namely, according to an exemplary embodiment, in the context of optional step 107, said Zn solution may comprise from about 1% to about 100%, e.g., about 90% of the total amount of Zn provided to the nanoparticles and may be added to the reactant solution after precipitating the Cu and Sn sources by chalcogenide addition, as in Example 1 (see below). Higher Zn content within the surface layer is believed to be important because it will help to keep the nanoparticles well-dispersed (i.e., not aggregating). It is to be understood that any alternative order of source addition may be employed to the same effect, by providing conditions sufficient to form elevated Zn content within the surface layer, for example by ion exchange reactions and aging in alkaline media, even if employing reverse source addition order (e.g., see Prestige above).

It is notable that the composition of the bulk volume of the nanoparticles (beneath the surface layer) can also be homogeneous or graded (layered), as long as the average Zn content of this bulk volume of the nanoparticles is lower than that of the surface layer. The formation process of the bulk volume of the nanoparticles can be influenced by the sequence of how the various metals are introduced into the reaction (i.e., adding in the Zn source later or with the other metals), the temperature of the reaction (higher temperature might favor more diffusion, making it harder to sustain a large composition gradient within the core) and the duration of the reaction (longer time may allow the metal ions to diffuse more to achieve an equilibrium concentration).

Optionally, in step 108, additional S and/or Se source compound can be added to the reactant solution after initial reaction in order to facilitate separation of the solid product from the solution. Namely, adding additional S and/or Se source compound serves to modify surface equilibria and render particles that can be centrifuged easily. For example, adding from about 2 percent (%) to about 4% of ammonium sulfide to the mixture enables efficient separation of the product by centrifugation at less than 14,000 g. See Example 1, described below.

The metal chalcogenide nanoparticles are a solid product of the reaction. With the above-described process, a dissolved product is also formed. For example, in the case where metal chlorides are used in the aqueous metal source solution, when the aqueous metal source solution is mixed with the chalcogen source solution ammonium chlorides are formed. These chlorides are considered to be contaminates since they may result in the formation of volatile metal compounds during the heat treatment crystallization step (see for example description of step 132, below). Accordingly, these contaminates are removed, for example, during the filtration/centrifugation and/or washing steps described below.

In step 110, the chalcogenide nanoparticles are extracted from the reaction solution using, for example, filtration, preferably using filters with a pore size of less than 1 micrometer and pressure difference, or centrifugation, preferably using greater than 1,000 g, more preferably greater than 10,000 g. A majority of the above-described contaminates (dissolved products) remain in the reaction solution and thus are removed from the nanoparticles during this step. Multiple centrifugation/filtration steps may be employed with an optional washing with a solvent in between. Any solvent that is not an effective solvent for the filtered product may be used. Suitable solvents include, but are not limited to water and alcohol. Washing involves rinsing the nanoparticle product with the solvent to remove any remaining contaminate species. Further, optionally, ammonium sulfide and/or ammonium selenide may be added to the solvent such that during the washing additional S and/or Se is reacted with the nanoparticles to facilitate separation of the solid product from the solution as described above. This addition of ammonium sulfide and/or ammonium selenide to the solvent may be done in conjunction with, or instead of, the additions of the same compounds made in step 108. The extracted nanoparticles can, in step 112, be washed with clean solvent (e.g., water or alcohol).

It has been found that the nanoparticles obtained by reacting chlorides of zinc, copper and optionally tin with ammonium sulphide and/or selenide are so prone to dispersing in the naturally alkaline solutions during the washing step with distilled water that after washing they cannot be separated by centrifugation even at 40,000 g. Filtration of the obtained particles was also found to be extremely difficult.

The above observation demonstrates the superior ability of the particles to disperse without addition of organic additives and also supports the finding that, for the final ink fabrication, it is preferable therefore to use alkaline media for dispersing the chalcogenide nanoparticles. Namely, the final inks are preferably fabricated with a pH of 7 to 14, more preferably a pH of 9 to 14. These recommendations refer to the final ink and should not be confused with the following paragraph describing an alternative synthesis route for the nanoparticles themselves.

Alternatively, in step 114, the Zn, Cu and Sn may be first coprecipitated out of the aqueous source solution, i.e., before being contacted with the chalcogen source solution, targeting the formation of oxide, hydroxide or mixed oxide-hydroxide solids. This may be accomplished by adjusting the pH of the aqueous metal source solution to reduce the solubility of the metal ions. By way of example only, the pH of the aqueous metal source solution can be adjusted using a base, such as ammonium hydroxide. Precipitation of the metal ions will occur when the pH is greater than about 5 (see Example 2, described below). In step 116, an optional washing step is performed to purify the metal coprecipitate (e.g., Zn and Cu and optionally Sn coprecipitate). In this step, the metal coprecipitate is rinsed with a suitable solvent. Suitable solvents include, but are not limited to, water. Optionally an additional washing step with water or another solvent can be applied to the final nanoparticle product (see below). As highlighted above, these purification steps are undertaken in order to eliminate contaminate species, for example chloride ions that may result in the formation of volatile metal compounds during the heat treatment crystallization step (see for example description of step 132, below).

In step 118, the solid metal coprecipitate is mixed with the chalcogen source solution (prepared in step 104, above) (the mixture referred to hereinafter as a “reactant solution”). Stirring may be employed to aid in the mixing. As described above, whether Cu, Sn or both Cu and Sn are present in the coprecipitate and whether S, Se or both S and Se are present in the S and/or Se source solution depends on the desired composition of the nanoparticles and keserite film formed therefrom.

Mixing the solid metal coprecipitate with the chalcogen source solution effects the ion exchange and formation of highly dispersible metal chalcogenide nanoparticles within the reactant solution. As described above, this reaction occurs without the need for organic nanoparticle capping agents and without the need for elevated temperatures during particle formation. Namely, the reaction can be carried out at ambient temperatures thus reducing production costs or optionally, by way of example only, at a controlled temperature of from about 0° C. to about 100° C., e.g., from about 20° C. to about 50° C., may be employed.

Optionally, in step 120, additional Zn, S and/or Se source compound can be added to the reactant solution after initial reaction in order to facilitate separation of the solid product from the solution. As described above, adding additional S and/or Se source compound serves to modify surface equilibria and render particles that can be centrifuged easily. For example, adding from about 2% to about 3% of ammonium sulfide to the mixture enables efficient separation of the product by centrifugation at less than 14,000 g. See Example 1, described below.

Adding additional Zn source compound serves to enhance precipitate quality by capping the nanoparticles with Zn compounds. Thus, according to an exemplary embodiment, a Zn content within the surface layers of the nanoparticles is greater than a Zn content in the volume of the nanoparticles. As described above, the “surface layers of the nanoparticles” is the interface layer between the particle and the solution and may comprise a layer from an atomic or molecular thickness to a layer of about 0.25 times the diameter of the particle and may comprise either zinc chalcogenide compounds or mixed Cu(Sn)—Zn chalcogenides or oxychalcogenides with a content of zinc greater than the average zinc concentration. Depending on the specific morphology, this concentration difference can be measured by XPS and ICP or TEM EDX scanning of individual particles. Forming a Zn cap on the nanoparticles can be accomplished, for example, by contacting the nanoparticles with a solution containing Zn²⁺ ions (hereinafter “a Zn solution”). In the context of optional step 120 this can involve simply adding from about 1% to about 100%, e.g., about 90% of the Zn solution to the reactant solution after substantially completing copper and/or tin chalcogenide precipitation with a chalcogen source.

In step 122, the chalcogenide nanoparticles are extracted from the reaction solution using, for example, filtration preferably using filters with a pore size of less than 1 micrometer and pressure difference, or centrifugation, preferably using greater than 1,000 g, more preferably using greater than 10,000 g. Multiple centrifugation/filtration steps may be employed with an optional washing with a solvent in between. Any solvent that is not an effective solvent for the filtered product may be used. Suitable solvents include, but are not limited to water and alcohol. Washing involves rinsing the nanoparticle product with the solvent to remove any remaining contaminate species. Further, optionally, ammonium sulfide and/or ammonium selenide may be added to the solvent such that during the washing additional S and/or Se is reacted with the nanoparticles to facilitate separation of the solid product from the solution as described above. This addition of ammonium sulfide and/or ammonium selenide to the solvent may be done in conjunction with, or instead of, the additions of the same compounds made in step 120.

Finally, in step 124, an optional washing of the nanoparticle product may be conducted to remove any remaining contaminates, thereby further purifying the final product. As above, any suitable solvent, e.g., water, may be used in this step to wash the product.

Depending on the reaction conditions and availability/pricing of starting materials, it may be preferable to employ solid metal sources, dissolved metal sources or a mixture thereof. Whereas fully dissolved sources may enable more homogeneous reactions, optimally selected solid sources may act as matrixes for growth of chalcogenide nanoparticles with desired morphology. Regardless of which process is employed, e.g., using either fully or partially dissolved metal sources, as in steps 106-112, or solid metal sources, as in steps 114-122, the resulting products are metal chalcogenide solids comprising optionally amorphous matter and optionally nanoparticles. The term “nanoparticles,” as used herein, generally refers to an object having at least one dimension (e.g., width, length, diameter, etc.) in the range of from about 1 nanometer (nm) to about 1,000 nm, for example, from about 1 nm to about 200 nm, e.g., from about 5 nm to about 50 nm. The shape of the particles can be, but is not limited to, spheres, cubes, rods, flakes and stars. Techniques for forming metal chalcogenide nanoparticles are also described in U.S. patent application Ser. No. ______, filed herewith on the same day of ______, entitled “Process for Preparation of Elemental Chalcogen Solutions and Methods of Employing Said Solutions in Preparation of Kesterite Films,” designated as Attorney Reference Number YOR920110410US1, the entire contents of which are incorporated by reference herein.

According to the present techniques, said metal chalcogenide solids may be used to prepare an ink for fabricating kesterite films. To form the ink, in step 126, the metal chalcogenide solids are redispersed in a solvent to form a metal chalcogenide dispersion. Suitable solvents include, but are not limited to, water and a water/hydrazine mixture. Namely, according to an exemplary embodiment, water containing from about 0.1 mass to about 40% of hydrazine may be used. Optionally, one or more inorganic additives can be added to the metal chalcogenide dispersion to adjust elemental composition or enhance ink quality (e.g., by pH adjustment). Suitable inorganic additives for adjusting elemental composition include, but are not limited to, Sn, tin(II) sulfide SnS, tin(IV) sulfide (SnS₂), tin(II) selenide (SnSe), tin(IV) selenide (SnSe₂), S, Se. Suitable inorganic additives for adjusting pH include, but are not limited to, ammonia, and/or an ammonium compounds.

Redispersing can be accomplished by ultrasonication and/or rapid stirring with a stir bar. Other standard methods of agitation of the mixture of metal chalcogenide solids and solvent are also expected to be effective for redispersing the solids and may be used in accordance with the present teachings.

An advantage of the present invention is to avoid or reduce the necessity of enhancing organic additives within the ink, in particular organic polymers acting as binders, surfactants and/or extenders, as their function can be substantially engineered by adequate introduction of desirable dissolved components that are subsequently incorporated into the final composition or by controlling the surface chemistry of the nanoparticles (e.g., Zn-enrichment). Reducing the number of components reduces production costs and complexity and eliminating organic additives can lead to more impurity (e.g., carbon) free films after ink processing into a kesterite film. In some cases, organic additives can be conveniently eliminated, e.g., by thermal anneal in oxidizing atmosphere when oxide materials are targeted. Therefore, in cases where organic additive use is desirable the additives can be readily integrated into the process. In such cases, the ink may optionally contain one or more enhancing organic additives that improve the dispersion of the solid phase and/or the solubility of the liquid phase and/or the rheological properties of the ink. Some non-limiting examples of such organic additives include: binders, viscosity modifiers, dispersants, wetting agents and/or solubility enhancers, such as, polymers, surface active compounds, complex forming agents, e.g., amines.

The nanoparticle ink may then be used to fabricate a kesterite film on a given substrate. According to an exemplary embodiment, the kesterite film formed has the following composition:

Cu₂₋ₓZn_{1+y}Sn(S_{1-z}Se_{z})_{4+q},

wherein 0≦x≦1; 0≦y≦1; 0≦z≦1; −1≦q≦1, e.g., 0≦x≦0.5; 0≦y≦0.5; 0≦z≦1; −0.5≦q≦0.5. As described above, the amounts of the components in the metal source solution and the chalcogen source solution can be tailored to achieve metal chalcogenide solids (e.g., nanoparticles) and subsequent kesterite films of the desired composition. This tailoring may be necessary in the cases as highlighted above where some of the metals are found to redissolve during processing, as may be the case with Sn during washing (see below). Namely, either the starting metal concentration can be adjusted to compensate for this redissolution and loss during washing, or an adjustment amount of Sn source can be added to the final ink during film deposition (see example). A calibration analysis of the ink composition to determine the adequate additive amount can be carried out by any technique known to those skilled in the art, such as but not limited to ICP, EDX and RBS (the latter requires analyzing the final film rather than the starting nanoparticles).

To form the kesterite film, in step 128, the ink (i.e., nanoparticle dispersion (optionally with additives)) is first deposited as a kesterite precursor film/layer onto a substrate. The resulting film is considered a precursor to the kesterite film at this point because it has not yet been heated to react the metal and chalcogen species present in the film to form the final desired crystalline kesterite film. By way of example only, suitable substrates include, but are not limited to, a metal foil substrate, a glass substrate, a ceramic substrate, aluminum foil coated with a (conductive) layer of molybdenum, a polymer substrate, and any combination thereof. It is preferable that the substrate is coated with a conductive coating/layer (such as a molybdenum layer) if the substrate material itself is not inherently conducting. Namely, the present techniques may be employed to form an absorber layer of a photovoltaic device (see below). The conductive coating/layer or substrate can, in that instance, serve as an electrode of the device. The nanoparticle ink may be deposited on the substrate using spin-coating, dip-coating, doctor blading, curtain coating, slide coating, spraying, slit casting, meniscus coating, screen printing, ink jet printing, pad printing, flexographic printing or gravure printing.

Optionally, in step 130, the deposited kesterite film is dried at a temperature that is below the boiling point of the solvent used in step 126 to redisperse the nanoparticles. Alternatively, the drying step may be incorporated into the heat treat process as a sub-step provided that conditions sufficient for forming an integral layer are met (e.g., avoiding boiling and bubble formation). By way of example only, water solutions, optionally containing hydrazine from about 0.1 mass % to about 40 mass % (as provided above) may be dried at ambient temperature and pressure or optionally at reduced pressure and/or temperature from about 20° C. to about 100° C. for periods of time ranging, for example, from about 2 seconds to about 60 minutes.

In step 132, a heat treatment (annealing) of the kesterite precursor film is performed. Namely, the kesterite precursor film is heated to a temperature sufficient to induce reaction and grain growth among the nanoparticles therein to form a film with an average grain size (measured in any particle dimension) of greater than 50 nm, e.g., greater than 200 nm, with predominantly the kesterite structure and composition. The film produced in this manner preferably contains at least 80% by mass of the targeted compound, more preferably at least 90% by mass of the targeted compound and even more preferably at least 95% by mass of the targeted compound. The targeted compound is the kesterite compound of the formula provided above.

According to an exemplary embodiment, the heat treatment involves heating the kesterite film to a temperature of from about 300° C. to about 700° C., preferably from about 400° C. to about 600° C. for a duration of from about 1 minute to about 120 minutes, e.g., from about 2 minutes to about 30 minutes. The step of heat treating is preferably carried out in an atmosphere including at least one of nitrogen, argon, helium, forming gas, and a mixture containing at least one of the foregoing gases. This atmosphere can further include vapors of at least one of S, Se and a compound containing S and/or Se to compensate for elemental loss and, by precise vapor concentration control (determined empirically for the specific reaction configuration) to tune the final S and Se content and/or distribution in the film. Namely, a S/(S+Se) ratio from 0.05 to 1 may be used. The atmosphere might additionally include Sn vapors, for example, if a source of Sn was not originally included in the aqueous metal source solution (see above).

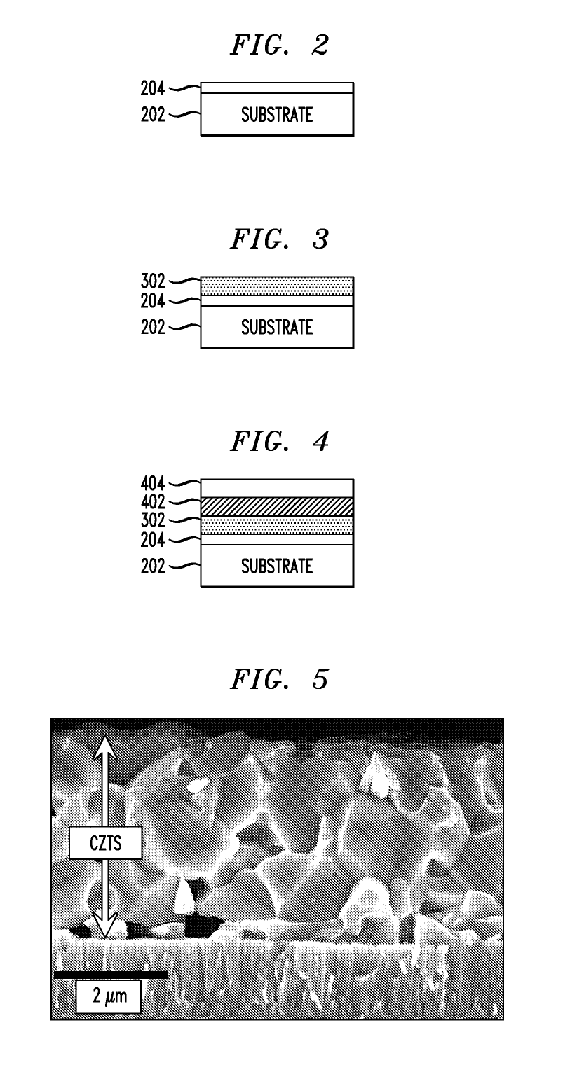

The present techniques may be employed in the fabrication of a photovoltaic device. See, for example, FIGS. 2-4. To begin the photovoltaic device fabrication process, a substrate 202 is provided. See FIG. 2. Suitable substrates were provided in conjunction with the description of step 128 of FIG. 1, above. Further, as described above, if the substrate material itself is not inherently conducting then the substrate is preferably coated with a conductive coating/layer. This situation is depicted in FIG. 2, wherein the substrate 202 has been coated with a layer 204 of conductive material. Suitable conductive materials for forming layer 204 include, but are not limited to, molybdenum (Mo), which may be coated on the substrate 202 using e.g., sputtering or evaporation.

Next, as illustrated in FIG. 3, a kesterite film 302 is formed on the substrate 202. In the particular example shown in FIG. 3, the substrate 202 is coated with the conductive layer 204 and the kesterite film 302 is formed on the conductive layer 204. Kesterite layer 302 may be formed on the substrate 202 using the techniques described in conjunction with the description of methodology 100 of FIG. 1, above. The kesterite film 302 will serve as an absorber layer of the device.

An n-type semiconducting layer 402 is then formed on the kesterite layer 302. According to an exemplary embodiment, the n-type semiconducting layer 402 is formed from zinc sulfide (ZnS), cadmium sulfide (CdS), indium sulfide (InS), oxides thereof and/or selenides thereof, which is deposited on the kesterite layer 302 using e.g., chemical bath deposition, electrochemical deposition, chemical vapor deposition or evaporation. Next, a top electrode 404 is formed on the n-type semiconducting layer 402. As highlighted above, the substrate 202 (if inherently conducting) or the layer 204 of conductive material serves as a bottom electrode of the device. Top electrode 404 is formed from a transparent conductive material, such as doped zinc oxide (ZnO), indium-tin-oxide (ITO), doped tin oxide or carbon nanotubes. The process for forming an electrode from these materials would be apparent to one of skill in the art and thus is not described further herein.

Advantageously, photovoltaic devices fabricated according to the present techniques operate with high performance. High performance is defined herein as greater than 6% photoelectric conversion efficiency. See Example 1.3, described below.

The present invention further provides a photovoltaic module which includes a plurality of electrically interconnected photovoltaic devices described in the present invention. Electric interconnection may be achieved either by connecting individually completed devices or by monolithic series interconnection on a large substrate by producing insulation scribes in the different layers by any technique known to the skilled in the art such as but not limited to laser scribing and mechanical scribing.

The present techniques are further described by way of reference to the following non-limiting examples.

### EXAMPLE 1

Particle dispersion preparation: zinc chloride (ZnCl₂) (0.067 grams (g)), copper chloride (CuCl₂) (0.967 g), and tin chloride (SnCl₂) (0.765 g) were dissolved in 30 milliliters (ml) of water (full dissolution can be achieved by addition of HCl, but in this example this was not targeted and the mixture had a white opaque aspect due to partial hydroxide formation). Under stirring, 5 ml 12 percent (%) (approx.) ammonium selenide solution was added, followed by addition of a solution of ZnCl₂ (0.600 g) in 10 ml water and finally 5 ml 20% ammonium sulfide solution. The solution was sonicated for 10 minutes, stirred again and separated by two consecutive cycles of centrifugation and washing with from about 2% to about 3% aqueous ammonium sulfide. The final wet cake was dispersed with the addition of water to form dispersion A with a total volume of 12 ml.

### EXAMPLE 1.1

Coating ink preparation: Coating ink B was prepared by mixing 3 ml of dispersion A, 1 ml of water and Solution C containing 1.5 ml hydrazine, 1.2 ml water, 0.23 g Se, 0.05 g SnS.

### EXAMPLE 1.2

Film deposition: One layer of the ink was spin-coated at 500 revolutions per minute (rpm) followed by 5 layers at 250 rpm. Each layer was annealed at 425° C. before the next layer was deposited. Solution D, containing 1 g Se and 0.05 g SnS in 4.5 ml 33% aqueous hydrazine, was coated on top at 800 rpm and the sample was annealed on a hot plate preset at 600° C. for 10 minutes. An image of the film prepared is provided in FIG. 5. As demonstrates in FIG. 5, kesterite grains larger than 1 micrometer in at least one dimension can readily be achieved using this technique. The use of capping layers in the fabrication of kesterite films is described in U.S. patent application Ser. No. ______, filed herewith on the same day of ______, entitled “Capping Layers for Improved Crystallization,” designated as Attorney Reference Number YOR920110408US1, the entire contents of which are incorporated by reference herein.

### EXAMPLE 1.3

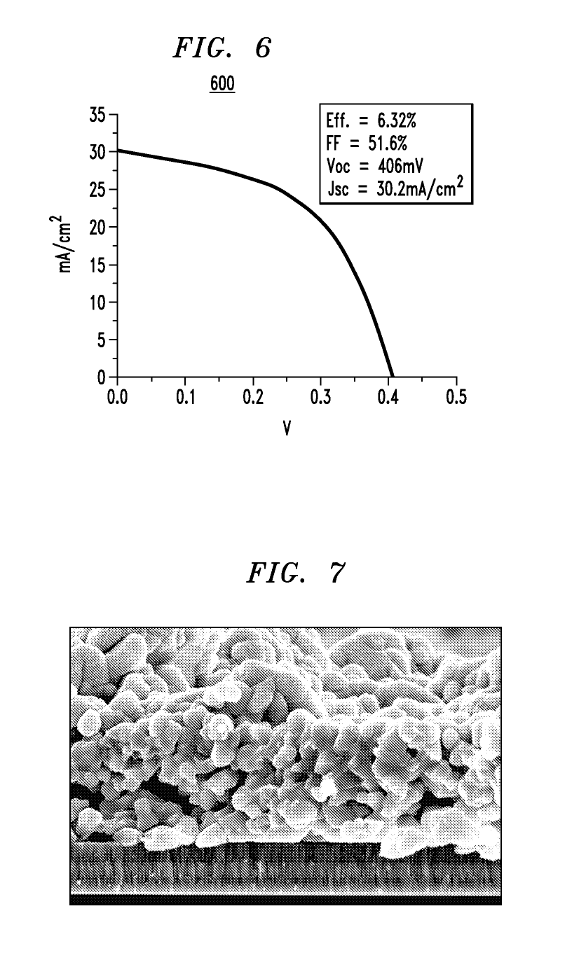

Device Fabrication: Solar cells with approximate area of 0.45 square centimeters (cm²) were fabricated from the obtained kesterite film by deposition of 60 nm CdS buffer layer by chemical bath deposition, 100 nm insulating ZnO and 130 nm ITO (indium-doped zinc oxide) by sputtering, Ni/Al metal contact grids by e-beam evaporation. Power conversion efficiency of 6.3%, under 1.5 AM standard illumination conditions was measured with open circuit voltage (Voc)=406 mV, fill factor (FF)=51.6% and short circuit current density (Jsc)=30 mA/cm². FIG. 6 is a graph 600 illustrating current-voltage characteristics of the device. In graph 600, voltage (v) is plotted on the x-axis and current density (measured in milliamps per square centimeter (mA/cm²) is plotted on the y-axis.

### EXAMPLE 2

ZnCl₂ (1.19 g) and CuCl₂ (2.15 g) were dissolved in 125 ml of water and the solution pH was adjusted to 7.5 by ammonium hydroxide addition. The precipitate was filtered and washed with water. 1.3 g of the wet cake (containing from about 20% to about 40% solid) was mixed with 2 ml ammonium sulfide solution (50% in water), stirred thoroughly, sonicated for 40 minutes and then stirred overnight.

A blade with 25 micron gap was used to deposit three layers on a molybdenum-coated glass substrate. Each layer was annealed at 425° C. for 2 minutes. The samples were sealed in quartz tubes with addition of from about 2 milligrams (mg) to about 3 mg SnS₂ and from about 2 mg to about 3 mg S or Se and annealed in evacuated quartz tubes for 40 minutes at 575° C. with a heating rate of 20° C. and natural cooling. An image of one of the S treated films is shown in FIG. 7 and an image of one of the Se treated films is shown in FIG. 8. In this example, therefore, the Sn for the kesterite composition is provided by a vapor-phase treatment after the deposition of a film containing the correct stoichiometry of Cu and Zn.

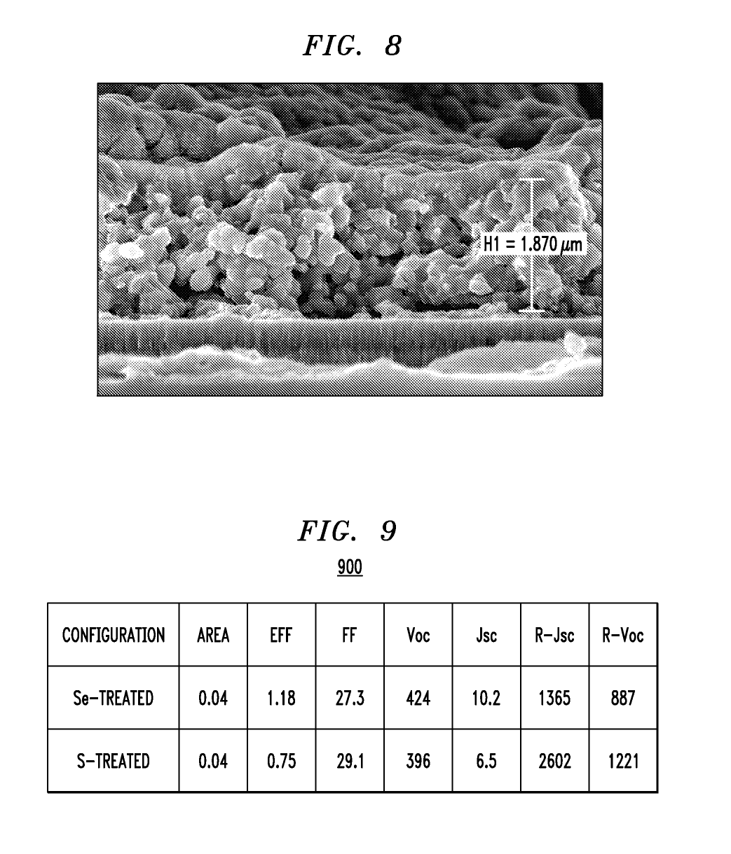

Devices were fabricated as in Example 1 but no metal grid was deposited due to the small area of the devices (0.04 cm²). Relatively low conversion efficiency was obtained, due to high series resistance. See FIG. 9. FIG. 9 is a table 900 illustrating area, efficiency (Eff), FF, Voc, Jsc, series resistance R-Jsc and parallel resistance R-Voc for these devices. Further optimization of vapor treatment conditions is expected to improve this efficiency.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A method of forming metal chalcogenide nanoparticles, the method comprising the steps of:
contacting water, a source of Zn, a source of Cu, optionally a source of Sn and at least one of a source of S and a source of Se under conditions sufficient to produce a dispersion of the metal chalcogenide nanoparticles having a Zn chalcogenide distributed within a surface layer thereof; and
separating the metal chalcogenide nanoparticles from the dispersion.

2. The method of claim 1, wherein a content of the Zn chalcogenide distributed within the surface layer of the metal chalcogenide nanoparticles is sufficient to inhibit agglomeration of the metal chalcogenide nanoparticles in water at a pH of from about 7 to about 14 without the use of organic additives or ligands.

3. The method of claim 1, wherein the metal chalcogenide nanoparticles are a homogeneous or heterogeneous mixture comprising at least one of amorphous and crystalline compounds.

4. The method of claim 1, wherein the said Zn chalcogenide distribution within the surface layer of the metal chalcogenide nanoparticles is achieved by use of an additional step of contacting the metal chalcogenide nanoparticles with an additional source of Zn and optionally an additional source of chalcogen.

5. The method of claim 1, wherein the source of Zn is selected from the group consisting of: elemental Zn, zinc oxide, zinc hydroxide, zinc bromide, zinc fluoride, zinc iodide, zinc chloride, zinc sulphate and zinc nitrate.

6. The method of claim 1, wherein the source of Cu is selected from the group consisting of: elemental Cu, copper oxide, copper hydroxide, copper bromide, copper fluoride, copper iodide, copper chloride, copper sulphate and copper nitrate.

7. The method of claim 1, wherein the source of Sn is selected from the group consisting of: elemental Sn, tin oxide, tin hydroxide, tin bromide, tin fluoride, tin iodide, tin chloride, tin sulphate and tin nitrate.

8. The method of claim 1, wherein the source of S is selected from the group consisting of: ammonium sulfide, alkali metal sulfide and hydrogen sulfide.

9. The method of claim 1, wherein the source of Se is selected from the group consisting of: ammonium selenide, alkali metal selenide and hydrogen selenide.

10. The method of claim 4, wherein the additional source of Zn comprises Zn²⁺ ions.

11. The method of claim 1, wherein the nanoparticles are separated from the dissolved product using filtration or centrifugation.

12. The method of claim 11, further comprising the step of:
washing the metal chalcogenide nanoparticles with water containing at least one of a source of S and a source of Se.

13. The method of claim 1, wherein the conditions further comprise a temperature of from about 20° C. to about 50° C.

14. A method for forming an ink for fabricating a kesterite film having a formula Cu₂₋ₓZn_{1+y}Sn(S_{1-z}Se_{z})_{4+q}, wherein 0≦x≦1; 0≦y≦1; 0≦z≦1; −1≦q≦1, the method comprising the steps of:
forming metal chalcogenide nanoparticles according to the method of claim 1; and
dispersing the metal chalcogenide nanoparticles in a solvent to form the ink, wherein the ink has a pH of from about 7 to about 14.

15. The method of claim 14, wherein the solvent is selected from the group consisting of: water and a water-hydrazine mixture.

16. The method of claim 14, wherein the ink has a pH of from 9 to 14.

17. The method of claim 14, further comprising the step of:
adjusting the pH of the ink to greater than 7 using an inorganic additive.

18. The method of claim 17, wherein the inorganic additive is ammonium compound.

19. An ink for fabricating a kesterite film having a formula Cu₂₋ₓZn_{1+y}Sn(S_{1-z}Se_{z})_{4+q}, wherein 0≦x≦1; 0≦y≦1; 0≦z≦1; −1≦q≦1 formed by the method of claim 14.

20. A method of forming a kesterite film having a formula Cu₂₋ₓZn_{1+y}Sn(S_{1-z}Se_{z})_{4+q}, wherein 0≦x≦1; 0≦y≦1; 0≦z≦1; and −1≦q≦1, the method comprising the steps of:
forming an ink according to the method of claim 14;
depositing the ink onto a substrate to form a layer on the substrate; and
heating the layer at a temperature and for a duration sufficient to form the kesterite film.

21. The method of claim 20, wherein x, y, z and q respectively are: 0≦x≦0.5; 0≦y≦0.5; 0≦z≦1; and −0.5≦q≦0.5.

22. The method of claim 20, wherein the layer is heated to a temperature of from about 300° C. to about 700° C. for a duration of from about 1 minute to about 120 minutes to form the kesterite film.

23. The method of claim 20, wherein the substrate comprises one or more of a metal foil substrate, aluminum foil coated with a layer of molybdenum, a glass substrate with conductive coating, a ceramic substrate with conductive coating and a polymer substrate with conductive coating.

24. The method of claim 20, wherein the metal chalcogen nanoparticle dispersion is deposited onto the substrate using spin-coating, dip-coating, doctor blading, curtain coating, slide coating, spraying, slit casting, meniscus coating, screen printing, ink jet printing, pad printing, flexographic printing or gravure printing.

25. The method of claim 20, wherein the layer is heated in an atmosphere containing vapors of at least one of S, Se and Sn.

26. A kesterite film having a formula Cu₂₋ₓZn_{1+y}Sn(S_{1-z}Se_{z})_{4+q}, wherein 0≦x≦1; 0≦y≦1; 0≦z≦1; and −1≦q≦1 formed by the method of claim 20.

27. The kesterite film of claim 26, wherein x, y, z and q respectively are: 0≦x≦0.5; 0≦y≦0.5; 0≦z≦1; and −0.5≦q≦0.5.

28. A photovoltaic device with power conversion efficiency greater than 6%, comprising:
a substrate;
a kesterite film absorber layer having a formula Cu₂₋ₓZn_{1+y}Sn(S_{1-z}Se_{z})_{4+q}, wherein 0≦x≦1; 0≦y≦1; 0≦z≦1; and −1≦q≦1 formed on the substrate by the method of claim 20;
an n-type semiconducting layer on the kesterite film; and
a top electrode on the n-type semiconducting layer.
